(19) United States
(12) Patent Application Publication
(10) Pub. No.: US 2023/0333394 A1
(43) Pub. Date: Oct. 19, 2023

(54) Systems Having Peripherals With Magnetic Field Tracking

(71) Applicant: Apple Inc., Cupertino, CA (US)

(72) Inventors: Yuhao Pan, Sunnyvale, CA (US); Guangwu Duan, Cupertino, CA (US); Jeffrey A. Griffis, San Carlos, CA (US); John G. Elias, Townsend, DE (US); Krishna Prasad Vummidi Murali, Sunnyvale, CA (US); Michael A. Lehr, Saratoga, CA (US); Savas Gider, San Jose, CA (US); Stephen E. Dey, Capitola, CA (US)

(21) Appl. No.: 18/180,700

(22) Filed: Mar. 8, 2023

Related U.S. Application Data
(63) Continuation of application No. PCT/US2021/051195, filed on Sep. 21, 2021.
(60) Provisional application No. 63/081,251, filed on Sep. 21, 2020.

(51) Int. Cl. G02B 27/01; G01R 33/02; G06F 3/01; G06F 3/0354

(52) U.S. Cl. CPC G02B 27/0176; G02B 27/0172; G01R 33/0206; G06F 3/014; G06F 3/03545; G02B 2027/0192; G02B 2027/0138

(57) ABSTRACT

A head-mounted device or other electronic device may emit an alternating-current magnetic field. A wireless controller may have alternating-current magnetometers for monitoring the alternating-current field. The wireless controller may also have an accelerometer for measuring the orientation of the controller relative to the Earth's gravity and a direct-current magnetometer for measuring the orientation of the controller relative to the Earth's magnetic field. The alternating-current magnetometers may be three-coil magnetometers located at different locations in a controller housing. Using data from the alternating-current magnetometers, the direct-current magnetometer, the accelerometer, and/or other sensors, the wireless controller can determine the position and orientation of the wireless controller. This information can be wirelessly transmitted to the head-mounted device to control the head-mounted device.

This application is a continuation of international patent application No. PCT/US2021/051195, filed Sep. 21, 2021, which claims priority to U.S. provisional patent application No. 63/081,251, filed Sep. 21, 2020, which are hereby incorporated by reference herein in their entireties.

### FIELD

This relates generally to electronic devices, and, more particularly, to systems with peripherals that control head-mounted devices.

### BACKGROUND

Head-mounted devices and other electronic devices may be controlled by peripheral equipment. Some peripherals may operate wirelessly when supplying an electronic device with input.

### SUMMARY

A head-mounted device or other electronic device may emit an alternating-current magnetic field. A wireless controller may have alternating-current magnetometers for monitoring the alternating-current field. The wireless controller may also have an accelerometer for measuring the orientation of the controller relative to the Earth's gravity and a direct-current magnetometer for measuring the orientation of the controller relative to the Earth's magnetic field. Using components such as these, the wireless controller may determine the position and orientation of the wireless controller relative to the head-mounted device. This information can then be wirelessly transmitted to the head-mounted device to control the head-mounted device. The alternating-current magnetometers may be three-coil magnetometers located at different locations in a controller housing. Each three-coil alternating-current magnetometer may have three coils that are aligned along three respective axes that are linearly independent (none of the axes are parallel to each other). In an illustrative configuration, which may sometimes be described herein as an example, each three-coil alternating-current magnetometer may have three orthogonal coils. In some configurations, coils may share a common magnetic core. Coils may also have air cores or separate magnetic cores, if desired. In an illustrative arrangement, two or three coils of each alternating-current magnetometer may be wrapped around a common magnetic core.

The wireless controller may have additional components to help measure position and orientation. These components may include optical sensors such as cameras that form part of a visual inertial odometry system, self-mixing proximity sensors, and/or optical-flow-based visual inertial odometry system sensors. If desired, the wireless controller may have light sources that serve as visual reference points. A camera in a head-mounted device may track these visual reference points to help determine the position and orientation of the wireless controller.

### BRIEF DESCRIPTION OF THE DRAWINGS

FIG. 1 is a diagram of an illustrative system with a head-mounted device and controller in accordance with an embodiment.

FIG. 2 is schematic diagram of an illustrative system with a head-mounted device and controller in accordance with an embodiment.

FIG. 3 is a front view of an illustrative finger device in accordance with an embodiment.

FIG. 4 is a top view of an illustrative handheld device in accordance with an embodiment.

FIG. 5 is a side view of an illustrative stylus in accordance with an embodiment.

FIG. 6 is a side view of an illustrative tracking module that may be removably coupled to an electronic device in accordance with an embodiment.

FIG. 7 is a perspective view of illustrative magnetic field sensing coils in accordance with an embodiment.

FIG. 8 is a perspective view of an illustrative finger device that may serve as a controller in accordance with an embodiment.

FIG. 9 is a perspective view of a substrate with a pair of magnetic sensors for a finger device in accordance with an embodiment.

FIG. 10 is a side view of an illustrative finger device having magnetic sensors of the type shown in FIG. 9 in accordance with and embodiment.

FIG. 11 is a side view of another illustrative finger device with magnetic sensors in accordance with an embodiment.

### DETAILED DESCRIPTION

Electronic devices such as head-mounted devices and other electronic equipment may have buttons, touch sensors, and other input devices that gather user input directly. In some configurations, external accessories are used in controlling electronic devices. For example, peripherals such as wireless controllers may be used in controlling head-mounted devices, computers, cellular telephones, and other electronic devices. In an illustrative configuration, which is sometimes described herein as an example, controllers such as wearable wireless controllers, handheld wireless controllers, and other wireless controllers are used in controlling a head-mounted device or other electronic device.

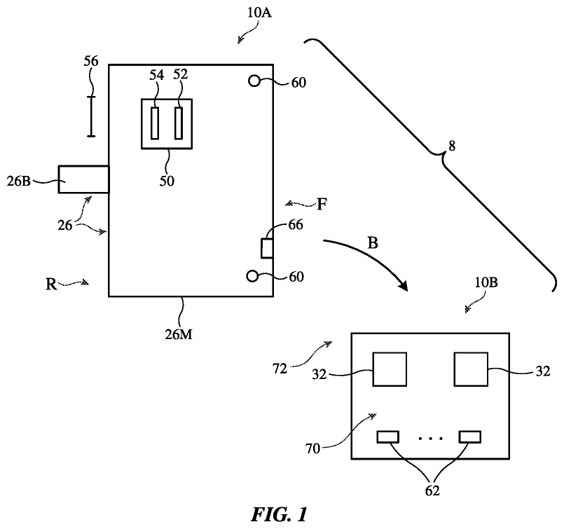

FIG. 1 is a diagram of an illustrative system in which an electronic device such as a head-mounted device is being wirelessly controlled by a peripheral device (sometimes referred to as an accessory or controller). As shown in FIG. 1, system 8 may include a controller such as wireless controller 10B that is used in wirelessly controlling an electronic device such as head-mounted device 10A. Wireless controller 10B may be worn on a user's finger, held in a user's hand, or removably coupled to a portable electronic device that is held in a user's hand or otherwise moved by a user.

In an illustrative configuration, which may sometimes be described herein as an example, device 10A is worn on the head of a user and controller 10B is worn on a finger of the user. As the user moves controller 10B (and optionally presses buttons, touches a touch sensor, applies force to a force sensor, or otherwise provides input to the controller), the position and orientation of controller 10B may be monitored by sensor circuitry in controller 10B (and, if desired, a camera or other sensor circuitry in device 10A). Information that controller 10B gathers on the position, orientation, and movement of controller 10B (and optional button press input and other input provided to controller 10B) serves as user input for device 10A.

User input from controller 10B may be provided wirelessly to device 10A in real time and used in controlling the operation of controller 10B. For example, user input supplied by controller 10B (and optionally gathered by a camera or other sensor in device 10A) may control the movement of elements in a game, may move a pointer, may be used in navigating through on-screen menu items and making menu selections, and/or may otherwise be used in controlling the user's interactions with device 10A.

As shown in FIG. 1, head-mounted device 10A may include head-mounted support structure 26. Support structure 26 may include main housing portion 26M and one or more straps such as strap 26B. Structure 26 may be configured to support device 10A on the head of a user. To present a user with images for viewing from eye boxes such as eye box 56, device 10A may include displays such as display 52 and lenses such as lens 54. These components may be mounted in optical modules such as optical module 50 (e.g., a lens barrel) to form respective left and right optical systems. There may be, for example, a left display for presenting an image through a left lens to a user's left eye in a left eye box and a right rear-facing display for presenting an image to a user's right eye in a right eye box. The user's eyes are located in eye boxes 56 at rear side R of device 10A when structure 26 rests against the outer surface of the user's face.

Main housing portion 26M may extend from rear side R of device 10A to opposing front side F of device 10. On rear side R, main housing portion 26M may have cushioned structures to enhance user comfort as portion 26M rests against the face of the user. If desired, device 10 may have optical components 66 (e.g., cameras, etc.). These cameras may, as an example, be mounted on front side F of portion 26M and may face in a forward direction away from displays 52. In some configurations, device 10A may have a publicly viewable front-facing display that is mounted on front side F of main housing portion 26M.

To create a magnetic field B that can be detected by controller 10B, device 10A may have one or more coils such as coil 60. In the example of FIG. 1, device 10A has a single ring-shaped coil (coil 60) with one or more turns running along the peripheral edge of portion 26M on front side F of device 10A, which may have a rectangular footprint, an oval shape, a shape with teardrop outlines on the left and right sides, and/or other suitable shape. Coil 60 may, as an example, run along the peripheral edge of a publicly viewable forward-facing display on front side F (e.g., around the outer edge of housing portion 26M). During operation of system 8, control circuitry in device 10A drives an alternating-current (AC) current through coil 60 to produce AC magnetic field B.

Controller 10B may have a housing such as housing 64. In an illustrative, controller 10B is a finger device or other wearable device and housing 64 is a finger-mounted housing or other wearable housing (body-mounted housing) configured to allow controller 10B to be worn on a finger or other body part of the user. Arrangements in which housing 64 is a portable device housing (e.g., a handheld device housing) may also be used.

Housing 64 may have walls or other structures that separate an interior region of controller 10B such as interior region 70 from an exterior region surrounding device 10 such as exterior region 72. Electrical components 62 (e.g., integrated circuits, sensors, control circuitry, light-emitting diodes, lasers, and other light-emitting devices, other control circuits and input-output devices, etc.) may be mounted on printed circuits and/or other structures within controller 10B (e.g., in interior region 70).

To sense AC magnetic field B and thereby determine the position and orientation of controller 10B relative to device 10A, controller 10B may have AC magnetic field sensors (sometimes referred to as AC magnetometers or AC magnetic sensors). In an illustrative configuration, device 10 has multiple AC magnetometers such as the illustrative pair of AC magnetometers 32 of FIG. 1.

Each AC magnetometer 32 may have one or magnetic sensing coils. By using a set of three orthogonal coils (e.g., coils wrapped around a common magnetic core formed of ferrite or other magnetic material), an AC magnetometer may measure the strength and direction of magnetic field B in three dimensions. Based on knowledge of the magnetic field distribution produced by coil 60 (e.g., from previous characterization measurements), controller 10B can use measurements of magnetic field B to determine the position and orientation of controller 10B relative to device 10A.

By using at least two AC magnetometers such as the illustrative pair of AC magnetometers 32 of FIG. 1, the accuracy with which controller 10B can determine the position and orientation of controller 10B relative to device 10B can be enhanced. Each of AC magnetometers 32 may be a three-coil magnetometer or, if desired, AC magnetometers with fewer coils can be used (e.g., a first of magnetometers 32 may be a three-coil magnetometer and a second of magnetometers 32 may be a one-coil or two-coil magnetometer). In some arrangements, controller 10B may have three or more AC magnetometers. Configurations in which controller 10B has first and second three-coil AC magnetometers located at different respective locations within interior 70 of housing 64 are sometimes described herein as an example.

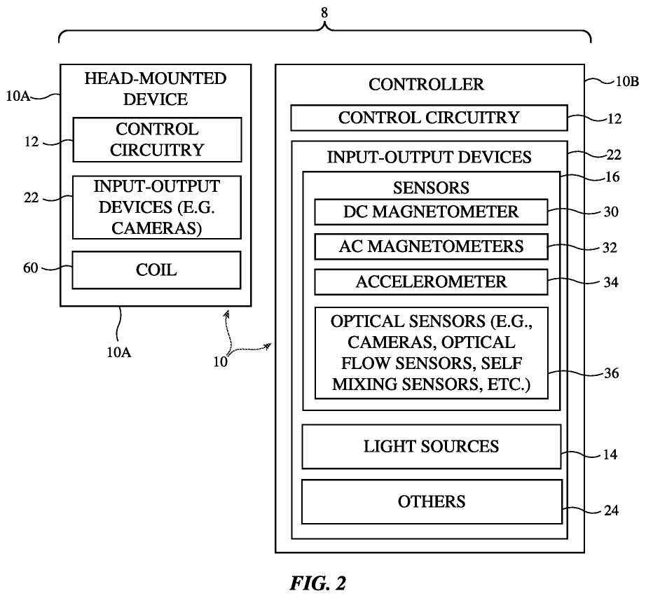

A schematic diagram of system 8 of FIG. 1 is shown in FIG. 2. As shown in FIG. 2, system 8 may include one or more electronic devices 10 such as head-mounted device 10A and controller 10B. In general, devices 10 may include head-mounted devices (e.g., device 10A of FIG. 1), controllers (e.g., controller 10B of FIG. 1), accessories such as headphones, computing equipment (e.g., a cellular telephone, tablet computer, laptop computer, desktop computer, etc.), and/or other electronic equipment (e.g., other electronic equipment controlled by controller 10B). Some devices (e.g., device 10A) may emit magnetic fields (e.g., AC magnetic field B of FIG. 1) and some devices (e.g., controller 10B and/or other peripherals with magnetic sensors) may sense these magnetic fields to determine their position and orientation relative to the emitting device(s). Arrangements in which head-mounted device 10A uses coil 60 to emit a magnetic field that is detected by magnetometers 32 in controller 10B are described herein as an example.

Each electronic device 10 in system 8 may have control circuitry 12. Control circuitry 12 may include storage and processing circuitry for controlling device operation. Circuitry 12 may include storage such as hard disk drive storage, nonvolatile memory (e.g., electrically-programmable-read-only memory configured to form a solid-state drive), volatile memory (e.g., static or dynamic random-access-memory), etc. Processing circuitry in control circuitry 12 may be based on one or more microprocessors, microcontrollers, digital signal processors, baseband processors, power management units, audio chips, graphics processing units, application specific integrated circuits, and other integrated circuits. Software code may be stored on storage in circuitry 12 and run on processing circuitry in circuitry 12 to implement control operations (e.g., data gathering operations, operations involving the adjustment of the components of an electronic device using control signals, etc.). Control circuitry 12 may include wired and wireless communications circuitry. For example, control circuitry 12 may include radio-frequency transceiver circuitry such as cellular telephone transceiver circuitry, wireless local area network transceiver circuitry (e.g., WiFi® circuitry), Bluetooth® transceiver circuitry, millimeter wave transceiver circuitry, and/or other wireless communications circuitry.

During operation, the communications circuitry of the devices in system 8 (e.g., the communications circuitry of control circuitry 12 of each electronic device 10) may be used to support communication between the electronic devices. For example, one electronic device may transmit video data, audio data, control signals, and/or other data to another electronic device in system 8. Electronic devices in system 8 may use wired and/or wireless communications circuitry to communicate through one or more communications networks (e.g., the internet, local area networks, etc.). The communications circuitry may be used to allow data to be received by a given device from external equipment (e.g., a tethered computer, a controller, a portable device such as a handheld device or laptop computer, online computing equipment such as a remote server or other remote computing equipment, or other electrical equipment) and/or to provide data to external equipment. As an example, a first device such as a wireless controller may use the wireless communications circuitry of circuitry 12 (e.g., Bluetooth circuitry, etc.) to wirelessly transmit information on the position and orientation of the wireless controller to a head-mounted device. In this way, the wireless controller may control the head-mounted device in real time. The head-mounted device may operate as a stand-alone device and/or may receive video, game content, and/or other content from a companion device (e.g., a laptop computer, cellular telephone, tablet computer, etc.). In arrangements in which system 8 includes a head-mounted device, a wireless controller, and a companion device that operates in conjunction with the head-mounted device, wireless control signals from the wireless controller may be provided to the head-mounted device and/or the companion device (which may be considered to form part of a head-mounted device system).

Each device 10 in system 8 may include input-output devices 22. Input-output devices 22 may be used to allow a user to provide device 10 with user input. Input-output devices 22 may also be used to gather information on the environment in which device 10 is operating. Output components in devices 22 may allow device 10 to provide a user with output and may be used to communicate with external electrical equipment.

Input-output devices 22 may include displays, light-emitting diodes, lasers, and other components that produce light output, may include audio components such as speakers and microphones, may include buttons, touch sensors, force sensors, and other components that receive user input, may include sensors that measure the operating environment of system 8, may contain haptic output devices, and/or may contain other circuitry.

Different devices 10 may have different sets of input-output devices. As an example, controller 10B may or may not have a display. In an illustrative configuration, controller 10B is a finger device with a limited size, so displays may be omitted. Head-mounted device 10A, may include displays such as display 52 of FIG. 1 to display images for left and right eye boxes while device 10A is being worn on the head of the user. As another example, device 10A may have optical components such as cameras (see, e.g., camera 66 of FIG. 1). Cameras may be used, for example, to help track controllers such as controller 10B. Controller 10B may have cameras to help measure the motion of controller 10B or may not have any cameras.

Another potential difference in the components of devices 10 relates to sensing circuitry. To determine its position and orientation, controller 10B may have sensors 16 such as DC magnetometer 30 (sometimes referred to as a compass or DC magnetic sensor), AC magnetometers 32, and accelerometer 34 (as examples). Device 10A may have sensors such as these or one or all of these sensors may be omitted from device 10A.

Controller 10B of FIG. 2 may optionally have additional sensors for helping to determine the position and orientation of controller 10B. These additional sensors may include optical sensors 36 (e.g., cameras, optical flow sensors, self-mixing sensors, and/or other sensors that emit and/or detect light).

Light sources 14 may be provided in device 10B to create visible reference points on housing 64 (FIG. 1). Device 10A may use cameras such as camera 66 to detect the positions of light sources 14 to help track the position and orientation of device 10.

In general, devices 10 (e.g., head-mounted device 10A and/or controller 10B) may include any suitable sensor circuitry such as illustrative sensors 16 of FIG. 2. Sensors 16 may include, for example, three-dimensional sensors (e.g., three-dimensional image sensors such as structured light sensors that emit beams of light and that use two-dimensional digital image sensors to gather image data for three-dimensional images from dots or other light spots that are produced when a target is illuminated by the beams of light, binocular three-dimensional image sensors that gather three-dimensional images using two or more cameras in a binocular imaging arrangement, three-dimensional lidar (light detection and ranging) sensors, sometimes referred to as time-of-flight cameras or three-dimensional time-of-flight cameras, three-dimensional radio-frequency sensors, or other sensors that gather three-dimensional image data), cameras (e.g., two-dimensional infrared and/or visible digital image sensors), gaze tracking sensors (e.g., a gaze tracking system based on an image sensor and, if desired, a light source that emits one or more beams of light that are tracked using the image sensor after reflecting from a user's eyes), touch sensors, capacitive proximity sensors, light-based (optical) proximity sensors, other proximity sensors, force sensors (e.g., strain gauges, capacitive force sensors, resistive force sensors, etc.), sensors such as contact sensors based on switches, gas sensors, pressure sensors, moisture sensors, magnetic sensors, audio sensors (microphones), ambient light sensors, flicker sensors that gather temporal information on ambient lighting conditions such as the presence of a time-varying ambient light intensity associated with artificial lighting, microphones for gathering voice commands and other audio input, sensors that are configured to gather information on motion, position, and/or orientation (e.g., accelerometers such as accelerometer 34, gyroscopes, compasses such as magnetometer 30, and/or inertial measurement units that include all of these sensors or a subset of one or two of these sensors), and/or other sensors.

User input and other information may be gathered using sensors and other input devices in input-output devices 22. If desired, input-output devices 22 (in device 10A and/or controller 10B) may include other devices 24 such as haptic output devices (e.g., vibrating components), light-emitting diodes, lasers, and other light sources (e.g., light-emitting devices that emit light that illuminates the environment surrounding device 10 when ambient light levels are low), speakers such as ear speakers for producing audio output, circuits for receiving wireless power, circuits for transmitting power wirelessly to other devices, batteries and other energy storage devices (e.g., capacitors), joysticks, buttons, and/or other components.

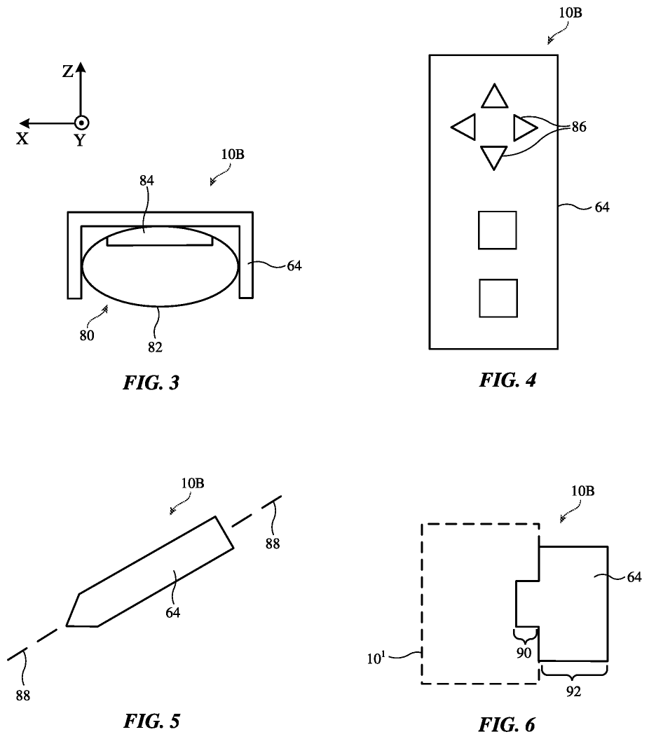

As described in connection with FIG. 1, housing 64 of controller 10B may allow controller 10B to be worn by a user, to be held in a user's hand, to be attached to an electronic device such as a handheld device, and/or to otherwise be manipulated by a user during operation of system 8. Illustrative configurations for housing 64 of controller 10B are shown FIGS. 3, 4, 5, and 6.

As shown in FIG. 3, housing 64 may be configured to be worn on the user's finger (finger 80). Housing 64 may, as an example have a U-shaped cross-sectional profile that covers fingernail 84 while leaving some or all of finger pad 82 on the lower surface of finger 80 exposed. Configurations in which housing 64 covers finger pad 82 and/or in which the housing for controller 10B is configured to form a glove, ring, wristband, arm band, and/or other structures mounted on a user's finger(s), wrist, hand, or other body part, may also be used.

In the example of FIG. 4, controller 10B serves as a handheld remote control. As shown in FIG. 4, housing 64 may be configured to support input-output devices such as buttons 86 in locations where buttons 86 may be pressed by a user's fingers as the user is holding housing 64 in the user's hand.

FIG. 5 is a side view of controller 10B in an illustrative configuration in which housing 64 has an elongated shape that extends along longitudinal axis 88. Housing 64 may, as an example, have a pointed tip that allows controller 10B to serve as a computer stylus (sometimes referred to as a pencil) that supplies input to a companion device such as a cellular telephone, laptop, or tablet computer with a display overlapped by a two-dimensional capacitive sensor.

In the illustrative arrangement of FIG. 6, controller 10B is a plug-in module. Housing 64 may have a portion such as portion 92 in which input-output devices 22 (e.g., AC magnetometers 32 and other sensors 16) and control circuitry 12 are mounted. Housing 64 may also have a portion such as portion 90 with contacts that form a connector. The connector may, as an example, be configured to plug into a matching connector on a cellular telephone or other handheld electronic device in system 8 (e.g., device 10′ of FIG. 6). In this type of configuration, controller 10B may measure magnetic fields and may otherwise be used in determining the position and orientation of housing 64 and attached device 10′ (e.g., controller 10B and device 10′ may collectively form a handheld wireless controller for device 10A). The connector formed by portion 90 may be detachable, so that controller 10B may be decoupled from device 10′ following use.

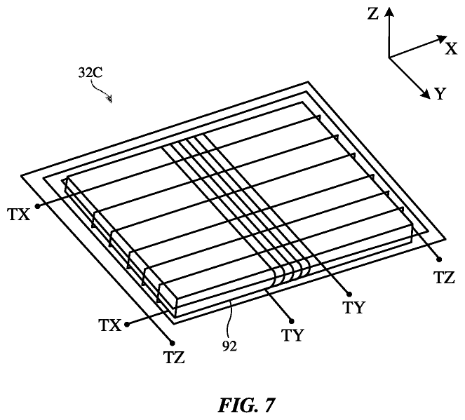

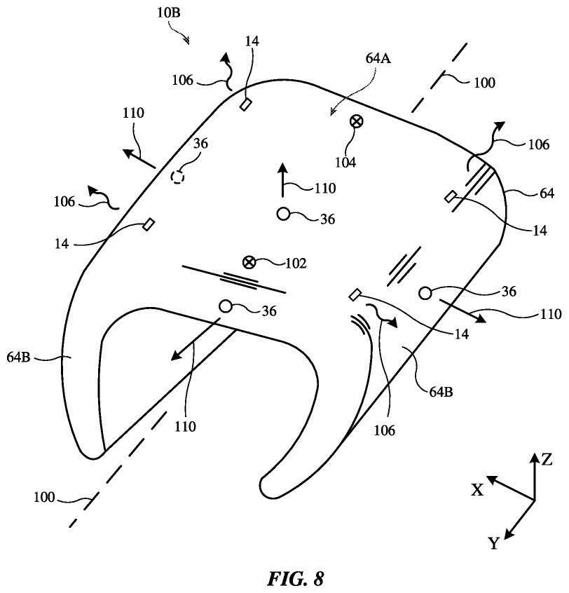

FIG. 7 is a perspective view of illustrative coils of the type that may be used in AC magnetometers 32. There are three coils 32C in the example of FIG. 7. These coils include an X-dimension coil with terminals TX that is configured to sense X-axis magnetic fields, a Y-dimension coil with terminals TY that is configured to sense Y-axis magnetic fields, and a Z-dimension coil with terminals TZ that is configured to sense Z-axis magnetic fields. Each of these three coils may have any suitable number of turns. The coils may share a common magnetic core such as core 92. The three coils in this example are oriented orthogonally to each other, which allows controller 10B to measure the strength and orientation of AC magnetic field B. Controller 10B (and/or device 10A) may contain a map of the three-dimensional magnetic field B (e.g., magnetic field strength and orientation). The map may be represented functionally, using look-up tables, or using any other suitable magnetic field map representation. Because the distribution of magnetic field B is known, measurements of the strength and orientation of field B can be used to determine where controller 10B is located relative to head-mounted device 10A, even in the event that a user's head turns or device 10A is otherwise moved during use. This allows computer-generated objects in a game or other virtual content to be accurately positioned relative to controller 10B and allows controller 10B to be used to accurately interact with such displayed virtual content.

In an illustrative configuration, housing 64 is configured to be worn on a user's finger (e.g., controller 10B is a finger device). FIG. 8 is a perspective view of controller 10B in an arrangement in which housing 64 has been configured to form a finger-mounted device housing.

As shown in FIG. 8, housing 64 may have a horizontally extending top portion such as top portion 64A that is coupled to respective left and right downwardly protruding side portions 64B. When controller 10B is worn on a user's finger, the user's finger extends along the length of housing 64 (e.g., along longitudinal axis 100 of housing 64) between side portions 64B. While the user is wearing device 10A and is interacting with content displayed by device 10A, the user may move controller 10B about in the environment surrounding the user to control device 10A (e.g., to interact with the displayed content).

In some scenarios, controller 10B is moved through free space and may be used to supply device 10A with air gesture input. Magnetic sensors and other sensors 16 may detect the position, orientation, and changes in position and orientation of controller 10B during these free space movements, so that air gesture input may be used in controlling device 10A.

In other situations, the user's fingers (e.g., the user's finger pads) contact objects in the environment. Using sensors in controller 10B, controller 10B can detect contact between the user's fingers and external objects. For example, controller 10B may have force sensors such as strain gauges and/or other sensors 16 that are mounted in portions 64B. These sensors can detect pressure from a user's finger (e.g., the sides of the user's finger) as the user moves the user's finger pad surfaces across objects and/or presses the user's finger pad surfaces against objects. Accelerometer circuitry in controller 10B may also be used to detect when a user's finger strikes an external object. Sensor measurements such as these that detect user interactions with objects can serve as user input for controlling device 10A in addition to movement information gathered by using magnetic sensors and other sensor circuitry.

By using sensors 16, controller 10B can therefore monitor the user's finger motions and interactions with the external environment. For example, controller 10B can detect the locations and physical properties of external object surfaces by mapping the locations and forces associated with touching and pressing against these objects with the user's fingers and/or portions of controller 10B. User input in the form of air gestures and information on user interactions with physical objects can be used by device 10A in determining which content should be displayed for the user and in providing other output. In some situations, device 10 may provide control signals to controller 10B that cause controller 10B to supply the user's finger with haptic output (e.g., by activating one or more haptic output devices in controller 10B). Audio output supplied to the user with device 10A or a pair of associated headphones can also be adjusted based on user input gathered by controller 10B.

To measure the position and orientation of controller 10B accurately, controller 10B of FIG. 8 may have a pair of AC magnetometers 32. These magnetometers may be spaced apart within housing 64 so that more accurate magnetic field measurements can be made than would be possible using only a single magnetometer. For example, magnetometers 32 may be spaced apart along longitudinal axis 100 (e.g., at different locations along the Y axis of FIG. 8) and/or may be placed at different locations along the X and/or Z axes of FIG. 8. In an illustrative configuration, magnetometers 32 are located at positions such as forward position 102 and rearward position 104 in housing 64. Each position is influenced by different local conditions (e.g., different structures and/or components that locally influence magnetic fields) and is thereby subject to different sources of potential interference. By spatially separating the coils of the magnetometers from each other, sensor performance can be enhanced.

During operation, each AC magnetometer 32 may use its coils to measure AC magnetic field B in the X, Y, and Z directions and, from these measurements can determine the position of controller 10B in X, Y, and Z. By using two AC magnetometers 32 instead of a single magnetometer, readings from each magnetometer may be averaged or otherwise combined to ensure that X, Y, and Z position measurements are accurate.

Controller 10B may have an accelerometer such as accelerometer 34 of FIG. 2 (e.g., an accelerometer in an inertial measurement unit or a stand-alone accelerometer). The accelerometer may measure the force of the Earth's gravity on controller 10B and can therefore be used in gathering information on the angular orientation of controller 10B relative to the center of the Earth (e.g., by measuring the pitch and roll of controller 10B relative to the Earth's surface).

Another sensor that may be used in measuring the position and orientation of controller 10B is a DC magnetometer such as DC magnetometer 30 of FIG. 2. The DC magnetometer, which may be part of the inertial measurement unit or may be a stand-alone DC magnetic sensor unit, may gather compass readings on the Earth's magnetic field that reveal the angular orientation of housing 64 (e.g., yaw) relative to the Earth's poles.

If desired, a gyroscope (e.g., a micro-electromechanical systems gyroscope, sometimes referred to as an angular rate sensor or orientation sensor) may be used to measure the rate of change of angular orientation of controller 10B. Gyroscope output may be used in conjunction with accelerometer output and/or DC magnetometer output to assess the movement of controller 10B (e.g., accelerometer output, DC magnetometer output, and gyroscope output may be used together to monitor pitch, roll, and yaw relative to the earth).

By combining each these measurements, the position and orientation of controller 10B may be determined (e.g., six-degrees-of-freedom tracking may be accomplished in which AC magnetometers 32 measure position in X, Y, and Z, accelerometer 34 measures pitch and roll, DC magnetometer 30 measures yaw, and an optional gyroscope is used in measuring the rate of change in angular orientation of controller 10B to help enhance accuracy in angular orientation measurements).

If desired, controller 10B and/or device 10A may have additional components that assist system 8 in determining the position and orientation of controller 10B relative to device 10A. As an example, controller 10B may have light-emitting devices 14 on housing 64. Light-emitting devices 14 may include light-emitting diodes or lasers that operate at ultraviolet, visible, and/or infrared wavelengths. Each light-emitting device 14 may emit light (e.g., infrared light that is invisible to the user) from a different location on housing 64 (e.g. each of the top four corners of housing 64 in the example of FIG. 8). Camera 66 may be sensitive to the emitted wavelength of light (e.g., cameras such as camera 66 in device 10A may be used to capture infrared images in which light beams from devices 14 appear as bright dots). The known locations of devices 14 on housing 64 may allow devices 14 to serve as visual references to inform device 10A of the position and orientation of controller 10B. If desired, the pattern in which devices 14 are arranged may be asymmetrical to help uniquely identify the position and orientation of controller 10B relative to device 10A when observed by camera 66. Devices 14 may also be modulated with different modulation patterns and/or may have other attribute to help distinguish between different devices 14 (e.g., different wavelengths of output light, different illumination shapes, etc.).

During operation, camera(s) such as camera 66 of device 10A may capture images of controller 10B. The positions of light-emitting devices 14 in the captured images can be used to help determine the position and orientation of controller 10B relative to camera 66 (and therefore relative to device 10A), so long as camera 66 is able to view light-emitting devices 14 (e.g., so long as a clear line of sight is maintained between camera 66). Camera-based controller tracking (e.g., image processing operations performed on images that contain bright spots from light-emitting devices 14) may be used to supplement other forms of device tracking (e.g., position and orientation measurement operations involving AC magnetometers 32, the DC magnetometer 30, and accelerometer 34).

Another sensor arrangement that may be used in determining the position and orientation of controller 10B involves the use of optical sensors 36 in controller 10B. As shown in FIG. 8, for example, controller 10B may have one or more sensors 36 (e.g., one or more, at least two, at least three, at least four, etc.) that are orientated in different respective directions. In the FIG. 8 example, there are four optical sensors 36, which are orientated in four respective directions 110 (e.g., in the +X direction, −X direction, +Z direction, and +Y direction). Optical sensors 36 may be cameras (e.g., visible-light-sensitive and/or infrared-light-sensitive cameras), may be optical self-mixing sensors (e.g., visible or infrared self-mixing sensors), or may be optical flow sensors (e.g., optical flow sensors that operate at visible and/or infrared wavelengths).

In a first illustrative configuration, sensors 36 are cameras that capture images of the environment surrounding controller 10B. Camera images can be combined with inertial measurement unit output to form a visual inertial odometry (VIO) system that tracks movement of controller 10B.

In a second illustrative configuration, sensors 36 are self-mixing sensors. The self-mixing sensors may have visible or infrared semiconductor lasers that emit light that reflects back into the lasers. In each laser, the reflected light perturbs the laser current and optical output for that laser. By processing these signals using the principals of self-mixing interferometry, the distance between a self-mixing sensor and the external object can be measured, thereby helping to determine the relative position between controller 10B and eternal objects.

In a third illustrative configuration, optical-flow-based visual inertial odometry techniques are implemented to help track controller 10B. In this type of arrangement, each of sensors 36 is an optical-flow sensor (e.g., an infrared transmitter and receiver used to observe microscopic details of illuminated surfaces and thereby track movement of controller 10B relative to these surfaces). The output of the optical-flow sensors may be combined with internal measurement unit output to form an optical flow visual inertial odometry system.

In general, sensors 36 may be used in implementing any of these tracking techniques and any of these techniques may be used to help determine the position and location of controller 10B during operation. For example, output from a camera-based VIO tracking system, output from a self-mixing interferometry tracking system, output from an optical-flow-based VIO tracking system, and/or camera data from a tracking camera that is tracking light-emitting devices 14 may be combined with measurements of position in X, Y, and Z from AC magnetometers 32 and angular orientation measurements from accelerometer 34 and DC magnetometer 30

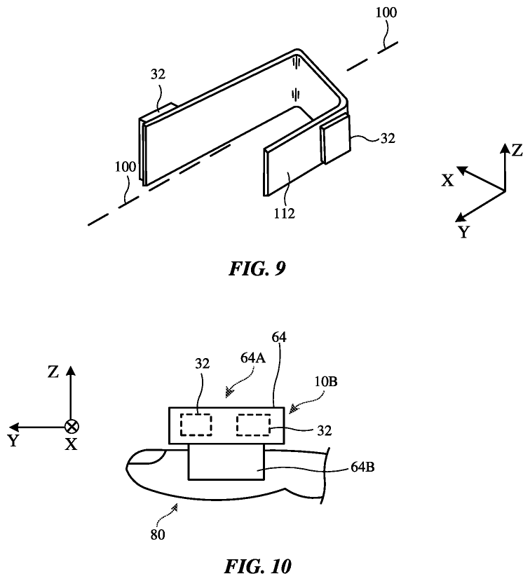

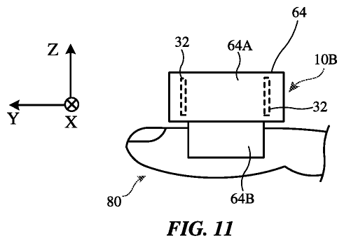

AC magnetometers 32 may be mounted at any suitable spatially separated locations within housing 64. FIG. 9 shows how a pair of AC magnetometers 32 may be attached to opposing ends of a flexible printed circuit such as printed circuit 112. Printed circuit 112 may be mounted in the interior of housing 64. As shown in FIG. 10, when mounted in housing 64, a first of AC magnetometers 32 of FIG. 9 may be located near the front of housing portion 64A and a second of AC magnetometers 32 of FIG. 9 may be located near the rear of housing portion 64A as device 10 is worn on a user's finger (finger 80).

In the example of FIGS. 9 and 10, the flat sides of magnetometer cores 92 have surface normals that face in the +X and −X directions. If desired, AC magnetometers 32 may be oriented so that the surface normals of the flat sides of magnetometer cores 92 are aligned along the Y-axis (e.g., the longitudinal axis of controller 10B). This type of arrangement is shown in the side view of controller 10B of FIG. 11. Other arrangements for the coils of AC magnetometers 32 may be used, if desired. The arrangements of FIGS. 9, 10 and 11 are illustrative.

In accordance with an embodiment, a wireless controller configured to wirelessly control a head-mounted device is provided that includes a housing configured to be worn by a user; a direct-current (DC) magnetometer in the housing; an accelerometer supported by the housing; a first alternating-current (AC) magnetometer at a first location in the housing; a second AC magnetometer at a second location in the housing that is different than the first location; and circuitry configured to: use information from the DC magnetometer, the first and second AC magnetometers, and the accelerometer to determine a position and orientation of the housing relative to the head-mounted device; and wirelessly transmit the position and orientation to the head-mounted device.

In accordance with another embodiment, the first AC magnetometer includes a three-coil magnetometer having a first three orthogonal coils wrapped around a first magnetic core and the second AC magnetometer includes a three-coil magnetometer having a second three orthogonal coils wrapped around a second magnetic core and the housing is a finger-mounted housing.

In accordance with another embodiment, the head-mounted device is configured to emit an AC magnetic field and the first and second AC magnetometers are configured to measure the AC magnetic field.

In accordance with another embodiment, the wireless controller includes light-emitting devices on the housing.

In accordance with another embodiment, the head-mounted device has a camera configured to monitor the light-emitting devices and the light-emitting devices include infrared light-emitting devices.

In accordance with another embodiment, the wireless controller includes a camera.

In accordance with another embodiment, the wireless controller includes a self-mixing sensor.

In accordance with another embodiment, the wireless controller includes an optical-flow sensor with a light emitter and a light detector.

In accordance with another embodiment, the wireless controller includes multiple cameras that capture images, the cameras are configured to form part of a visual inertial odometry system.

In accordance with another embodiment, the wireless controller includes plurality of infrared self-mixing sensors configured to gather information on distances between the housing and external objects.

In accordance with another embodiment, the wireless controller includes a plurality of optical-flow sensors configured to form part of a visual inertial odometry system.

In accordance with another embodiment, the housing is a computer stylus housing.

In accordance with another embodiment, the housing includes a handheld remote control housing.

In accordance with another embodiment, the wireless controller includes a connector configured to mate with a connector in a cellular telephone.

In accordance with an embodiment, a wireless wearable controller operable to control an electronic device that emits an alternating-current magnetic field is provided that includes

a wearable housing; alternating-current magnetometer circuitry configured to measure the alternating-current magnetic field; and control circuitry configured to wirelessly control the electronic device using information on the measured alternating-current magnetic field.

In accordance with another embodiment, the alternating-current magnetometer circuitry includes a first alternating-current magnetometer configured to measure the alternating-current magnetic field; and a second alternating-current magnetometer configured to measure the alternating-current magnetic field and the control circuitry is configured to wirelessly control the electronic device using information on the measured alternating-current magnetic field from the first and second alternating-current magnetometers.

In accordance with another embodiment, the first alternating-current magnetometer has three orthogonal coils.

In accordance with another embodiment, the second alternating-current magnetometer has at least two orthogonal coils.

In accordance with another embodiment, the wearable housing includes a finger-mounted housing and the second alternating-current magnetometer has three orthogonal coils, the wireless wearable controller includes a direct-current magnetometer; and an accelerometer, the control circuitry is configured to wirelessly control the electronic device using information from the direct-current magnetometer and the accelerometer.

In accordance with an embodiment, a wireless controller configure to control an electronic device emitting an alternating-current magnetic field is provided that includes a housing; a first three-coil alternating-current magnetometer that is configured to measure the alternating-current magnetic field; a second three-coil alternating-current magnetometer that is configured to measure the alternating-current magnetic field; a direct-current magnetometer configured to measure Earth's magnetic field; an accelerometer configured to measure Earth's gravity; and control circuitry configured to: determine a position of the housing in three orthogonal dimensions using first output from the first three-coil alternating-current magnetometer and using second output from the second three-coil alternating-current magnetometer; determine pitch and roll for the housing using output from the accelerometer; and determine yaw for the housing using output from the direct-current magnetometer.

In accordance with another embodiment, the housing includes a finger-mounted housing.

In accordance with another embodiment, the wireless controller includes cameras configured to form part of a visual internal odometry system.

The foregoing is merely illustrative and various modifications can be made to the described embodiments. The foregoing embodiments may be implemented individually or in any combination.

What is claimed is:

1. A wireless controller configured to wirelessly control a head-mounted device, comprising:
a housing configured to be worn by a user;
a direct-current (DC) magnetometer in the housing;
an accelerometer supported by the housing;
a first alternating-current (AC) magnetometer at a first location in the housing;
a second AC magnetometer at a second location in the housing that is different than the first location; and
circuitry configured to:
use information from the DC magnetometer, the first and second AC magnetometers, and the accelerometer to determine a position and orientation of the housing relative to the head-mounted device; and
wirelessly transmit the position and orientation to the head-mounted device.

2. The wireless controller defined in claim 1 wherein the first AC magnetometer comprises a three-coil magnetometer having a first three orthogonal coils wrapped around a first magnetic core and wherein the second AC magnetometer comprises a three-coil magnetometer having a second three orthogonal coils wrapped around a second magnetic core and wherein the housing is a finger-mounted housing.

3. The wireless controller defined in claim 2 wherein the head-mounted device is configured to emit an AC magnetic field and wherein the first and second AC magnetometers are configured to measure the AC magnetic field.

4. The wireless controller defined in claim 1 further comprising light-emitting devices on the housing.

5. The wireless controller defined in claim 4 wherein the head-mounted device has a camera configured to monitor the light-emitting devices and wherein the light-emitting devices comprise infrared light-emitting devices.

6. The wireless controller defined in claim 1 further comprising a camera.

7. The wireless controller defined in claim 1 further comprising a self-mixing sensor.

8. The wireless controller defined in claim 1 further comprising an optical-flow sensor with a light emitter and a light detector.

9. The wireless controller defined in claim 1 further comprising multiple cameras that capture images, wherein the cameras are configured to form part of a visual inertial odometry system.

10. The wireless controller defined in claim 1 further comprising plurality of infrared self-mixing sensors configured to gather information on distances between the housing and external objects.

11. The wireless controller defined in claim 1 further comprising a plurality of optical-flow sensors configured to form part of a visual inertial odometry system.

12. The wireless controller defined in claim 1 wherein the housing is a computer stylus housing.

13. The wireless controller defined in claim 1 wherein the housing comprises a handheld remote control housing.

14. The wireless controller defined in claim 1 further comprising a connector configured to mate with a connector in a cellular telephone.

15. A wireless wearable controller operable to control an electronic device that emits an alternating-current magnetic field, comprising:
a wearable housing;
alternating-current magnetometer circuitry configured to measure the alternating-current magnetic field; and
control circuitry configured to wirelessly control the electronic device using information on the measured alternating-current magnetic field.

16. The wireless wearable controller defined in claim 15 wherein the alternating-current magnetometer circuitry comprises:
a first alternating-current magnetometer configured to measure the alternating-current magnetic field; and
a second alternating-current magnetometer configured to measure the alternating-current magnetic field and wherein the control circuitry is configured to wirelessly control the electronic device using information on the measured alternating-current magnetic field from the first and second alternating-current magnetometers.

17. The wireless wearable controller defined in claim 16 wherein the first alternating-current magnetometer has three orthogonal coils.

18. The wireless wearable controller defined in claim 17 wherein the second alternating-current magnetometer has at least two orthogonal coils.

19. The wireless wearable controller defined in claim 17 wherein the wearable housing comprises a finger-mounted housing and wherein the second alternating-current magnetometer has three orthogonal coils, the wireless wearable controller further comprising:
a direct-current magnetometer; and
an accelerometer, wherein the control circuitry is configured to wirelessly control the electronic device using information from the direct-current magnetometer and the accelerometer.

20. A wireless controller configure to control an electronic device emitting an alternating-current magnetic field, comprising:
a housing;
a first three-coil alternating-current magnetometer that is configured to measure the alternating-current magnetic field;
a second three-coil alternating-current magnetometer that is configured to measure the alternating-current magnetic field;
a direct-current magnetometer configured to measure Earth's magnetic field;
an accelerometer configured to measure Earth's gravity; and
control circuitry configured to:
determine a position of the housing in three orthogonal dimensions using first output from the first three-coil alternating-current magnetometer and using second output from the second three-coil alternating-current magnetometer;
determine pitch and roll for the housing using output from the accelerometer; and
determine yaw for the housing using output from the direct-current magnetometer.

21. The wireless controller defined in claim 20 wherein the housing comprises a finger-mounted housing.

22. The wireless controller defined in claim 20 further comprising cameras configured to form part of a visual internal odometry system.
